(19) United States
(12) Patent Application Publication
(10) Pub. No.: US 2010/0218799 A1
(43) Pub. Date: Sep. 2, 2010

(54) PROCESS FOR CONNECTING PHOTOVOLTAIC CELLS IN SERIES, A PHOTOVOLTAIC CELL CONNECTABLE IN SERIES USING THE PROCESS, AND A MODULE OBTAINED WITH THE PROCESS

(75) Inventor: Franco Stefani, Sassuolo (IT)

Correspondence Address: Pearne & Gordon LLP, 1801 East 9th Street, Suite 1200, Cleveland, OH, 44114-3108, US

(73) Assignee: SYSTEM S.P.A., Fiorano Modenese (Modena) (IT)

(21) Appl. No.: 12/521,112

(22) PCT Filed: Oct. 12, 2007
(86) PCT No.: PCT/IT2007/000715

§ 371 Date: Jun. 24, 2009

(51) Int. Cl. H01L 31/042; H01L 31/00; B29C 65/00; B23K 31/02; B23K 1/20

(52) U.S. Cl. 136/244; 136/256; 156/60; 228/248.1

(57) ABSTRACT

A process for series connection of two photovoltaic cells (1a, 1b) in series, comprising following stages: predisposing a first photovoltaic cell (1a) and a second photovoltaic cell (1b), both of a type comprising a photosensitive semiconductor layer (2) provided with front contacts (3a, 3b) and back contacts (4) arranged on opposite surfaces of the cell; partially superposing the two photovoltaic cells (1a, 1b), causing at least a partial superposing of the back contact (4) of the first photovoltaic cell (1a) on the front contact (3a, 3b) of the second photovoltaic cell (1b) and consequently establishing an electrical contact between the back contact (4) and the front contact (3a, 3b).

### TECHNICAL FIELD

The invention is applicable to the field of energy production and relates in particular to a series connection for photovoltaic cells made of monocrystalline or polycrystalline silicon.

Environmental and economic reasons have contributed in recent times to a diversification of the sources of energy production. Special efforts have been dedicated to the sourcing of radiation energy coming from the Sun, using photovoltaic technology. This technology is especially appreciated because of the limited environmental impact deriving from its use, and thanks to the fact that it exploits an energy resource which is inexhaustible, i.e. renewable.

### BACKGROUND ART

Various technologies are known for making photovoltaic modules. The most widely present on the market, due to their inexpensiveness and relative reliability, are modules constituted by silicon cells, of a mono- or polycrystalline type.

These cells are constituted by sheets of semi-conductor material, practically always silicon applications, specially doped with atoms belonging to groups III or V in the periodic table, to realise a p-n junction. Each photon provided with sufficient energy and incident to the junction causes passage of one of the electrons present in the semi-conductor from the valence band to the conduction band, determining the presence of an electron-hole pair which cannot recombine because of the effect of the electrical field due to the p-n junction. There is therefore generation, in the presence of solar radiation, of a separation of electron-hole pairs and a consequent difference of potential between the two surfaces of the cell subdivided by the p-n junction. On these faces metal contacts are specially predisposed, functioning as collectors. In the example, a cell comprises a posterior electrical contact associated to the region of type p of the junction and an anterior electrical contact associated to the region of type n (the position of the regions can also be inverted); these contacts define the opposite poles of the tension generator constituted by the cell itself. In defining the anterior and posterior relations between elements of a photovoltaic cell, in the present document “anterior” is taken as referring to the closer element to the surface of the device exposed to sunlight.

The posterior electrical contact, known as back-contact, is constituted by a uniform conductive layer generally made of aluminium and silver. The upper layer, known as front-contact, must be specially constituted by a conductive trace lattice, typically made of silver. The trace lattice must have a geometry which is such that it does not prejudice exposition of the semiconductor back layer to the solar radiation. The efficiency of the cell is entirely and proportionally related to the area of the surface of the cell which is not covered by the above-mentioned lattice. The lattice constituting the upper contact comprises a plurality of very slim conductive traces, known as fingers, which cover the whole face of the cell, and a limited number of larger conductive traces connected to the fingers, known as busbars, which are load collectors.

The potential difference generated internally of a photovoltaic cell generally being very limited, in practical applications panels are preferably used, which panels internally comprise a predetermined number of series-connected cells.

In order to operate the series connection between two photovoltaic cells of the described type, it is necessary to establish an electrical connection between the busbars of the front contact of the first of the two cells and the back contact of the second cell.

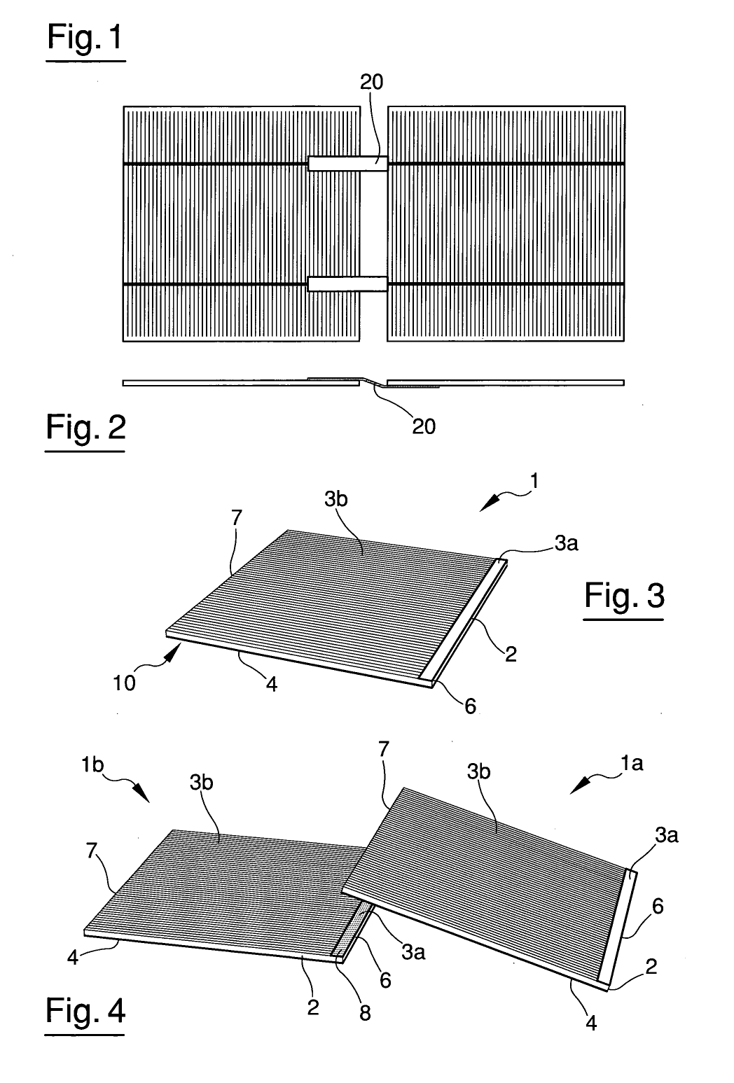

In known processes for series-connection of photovoltaic cells, the above-mentioned electrical connection between successive cells is realised by means of metal strings, known as ribbons, in a generally equal number to that of the busbars in the cell to be connected. The ribbons are constrained by soldering to the electrical contacts of two contiguous and juxtaposed cells. Once applied, the ribbon is fixed to one of the busbars of a cell and to the back contact of the contiguous cell. The two soldered ends are on different planes, and the string comprises a non-constrained tract that it extends obliquely or vertically in order to enable the connection between the planes. A series connection of photovoltaic cells via ribbons is illustrated in FIGS. 1 and 2 of the accompanying drawings, where the ribbon is denoted by the number 20. In the industrial production of photovoltaic panels, series assembly of the various cells is automated and fixture of the contiguous cells with ribbons is done by a machine known as a tab-stringer. Though these machines enable automation of the process, the fixing of the ribbons is the most delicate part of the assembly. This operation requires a considerable amount of time to be performed, leading to a high throughput time for the whole productive process. The inherent mechanical complexity of the tab-stringer machine also makes it particularly vulnerable to break-down.

The aim of the process for series connection of photovoltaic cells of the present invention is to enable assembly of the cells without having to resort to the use of the above-cited ribbons.

An advantage of the present process for series connection of photovoltaic cells is that it can easily be automated by means of an assembly line which is rapid and has a low vulnerability to breakdown.

### DISCLOSURE OF INVENTION

Further characteristics and advantages of the invention will better emerge from the detailed description that follows, made with reference to the accompanying figures of the drawings, given by way of non-limiting example, and in which:

FIG. 1 is a view from above of two photovoltaic cells, series-connected with to ribbons according to the prior art;

FIG. 2 is a lateral view of two photovoltaic cells, series-connected according to the prior art;

FIG. 3 is a perspective view of a photovoltaic cell according to the present invention;

FIG. 4 is a perspective view of two photovoltaic cells of the type illustrated in FIG. 3, about to be connected in series using the process of the present invention;

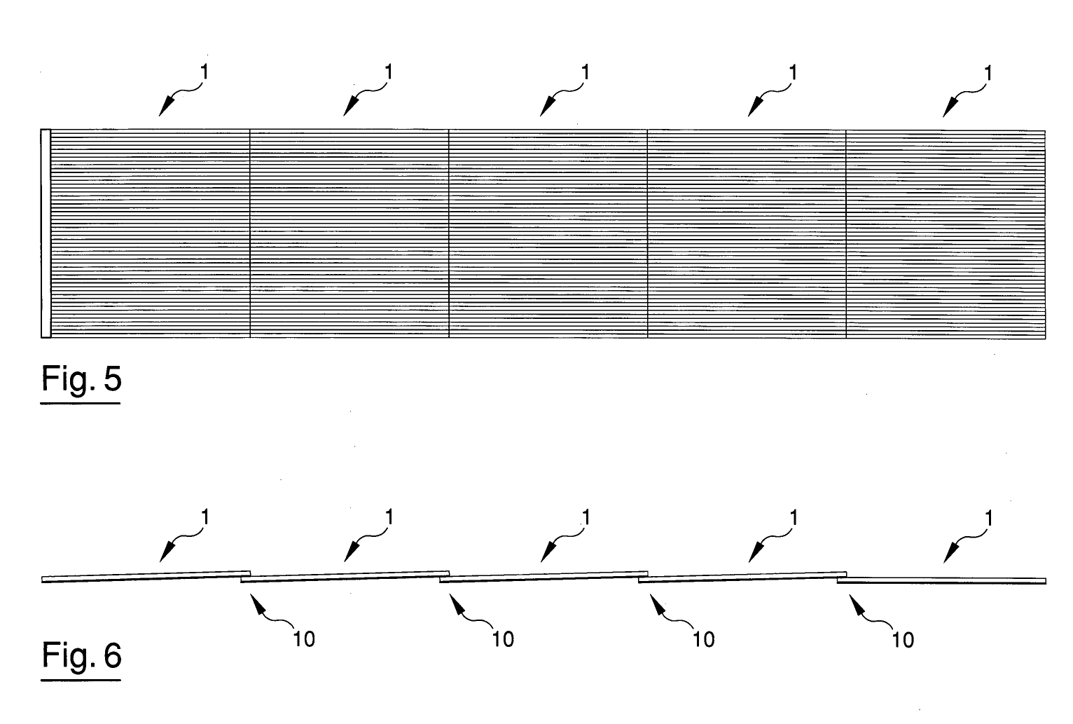

FIG. 5 is a view from above of a plurality of photovoltaic cells connected in series using the process of the present invention;

FIG. 6 is a lateral view of a plurality of photovoltaic cells connected in series using the process of the present invention;

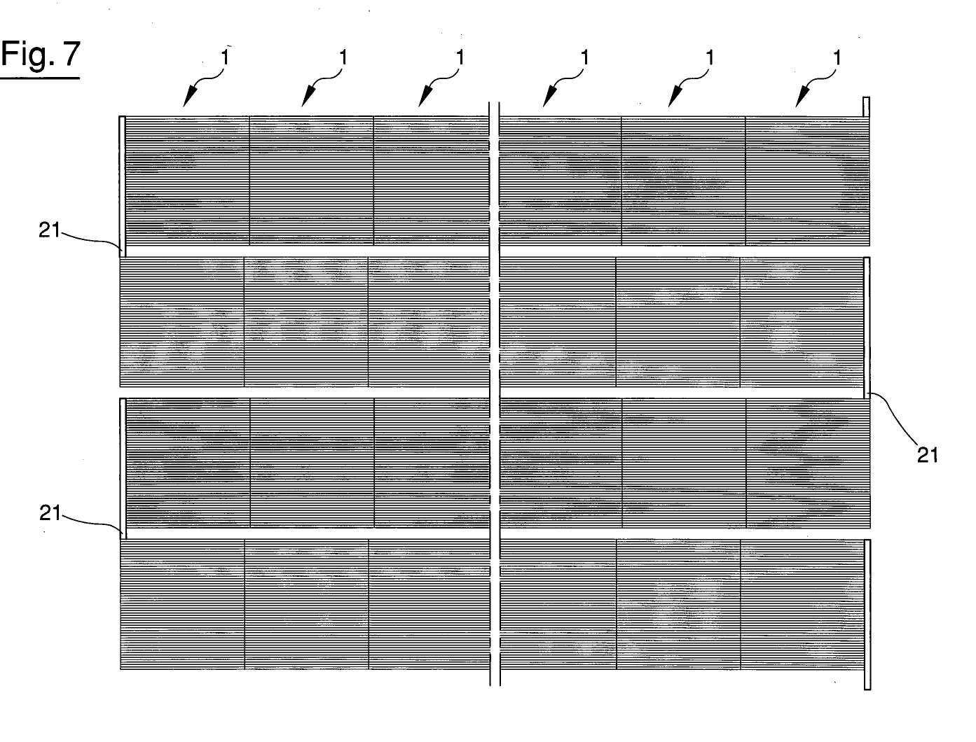

FIG. 7 is a view from above of a plurality of photovoltaic cells arranged on several rows, the cells of each single row being connected to each other in series using the process of the present invention.

With reference to the series connection of two photovoltaic cells 1a, 1b, the process of the present invention comprises the following known stages: predisposing a first photovoltaic cell 1a and a second photovoltaic cell 1b, both of a type comprising a photo-sensitive semi-conductor layer 2 provided with upper electric contacts 3a, 3b (front contacts) and lower electrical contacts 4 (back contacts) arranged on opposite surfaces of the cell; establishing an electrical connection between the front contact 3a, 3b of the second photovoltaic cell 1b and the back contact 4 of the first photovoltaic cell 1a. The process is characterised in that the stage of establishing an electrical connection between the electrical contacts 3a, 3b and 4 of the photovoltaic cells 1 comprises a stage of partially superposing the cells, causing an at least partial superposing of the back contact 4 of the first photovoltaic cell 1a on the front contact 3a, 3b of the second photovoltaic cell 1b and a consequent electrical connection between the contacts.

In the series connection of cells according to the above-described stages, the connection ribbon between contiguous cells is no longer necessary, as the electrical contact between successive cells is established thanks to the direct contact between back contact and front contract of the two cells. The problematic operation of fixing the ribbon is thus eliminated from the construction process.

The front contact 3a, 3b of the series-connected cells advantageously comprises at least a trace junction 3a arranged in proximity of a first perimeter edge 6 of the cell on which it is predisposed. Consequently, during the stage of partially superposing the cells, a contact portion 10 of the first cell is superposed on the trace junction 3a. In the discussion of the prior art it was mentioned that the lower surface of photovoltaic cells 1 is uniformly covered with a lower conductive layer 4, i.e. a back contact; the contact of the back-contact with the conductive trace junction 3a thus creates the desired series connection. The above-mentioned portion of contact 10 is advantageously a lateral portion of the cell which is contiguous to a second perimeter edge 7, opposite the first 6. The counter-positioning between the portion of contact 10 and the trace junction 3a also enables an easy series connection of more than two photovoltaic cells 1, as will be described herein below. By size and function, the trace junction 3a is similar to the busbars used in cells assembled according to the prior art; the trace is connected to a plurality of secondary traces, or fingers 3b, which develop on the upper surface of the cell.

The connecting process of the present invention can advantageously also comprise a stage for fixing the first and the second photovoltaic cells 1a, 1b in the above-described superposed configuration. This stage can include the interposing of a fixing substance 8 between the parts in contact of the two photovoltaic cells, in the example the back surface of the contact portion 10 of the first cell 1a and the trace junction 3a of the second cell 1b. The fixing substance 8 can be constituted by a glue, by an adhesive or by a paste with consolidating properties, for example by sintering, at normal temperature or at another temperature, even one above 80° C. For obvious reasons it is of fundamental importance that the fixing substance used should have excellent electrical conductive characteristics at normal environmental temperature. Unless the fixing stage is done with great care and precision, the above-described fixing substance 8 can solidify outside the space interposed between the contact portion 10 and the trace junction 3a, causing the risk of short-circuiting between the back contact 4 and the front contact 3a, 3b of a same cell. To eliminate these production defects, the process of the present invention can advantageously comprise a stage of electrically insulating the front contact 3a, 3b from the back-contact 4 of the first photovoltaic cell 1a at the second perimeter edge 7 thereof and a stage of electrically insulating the trace junction 3a from the back contact 4 of the second photovoltaic cell 1b at the first perimeter edge 6 thereof. The electrical insulation can be achieved by used of insulating lacquers or by burning the edge, using, for example, laser burners, or even using other known systems.

Obviously, the above-described process for series-connection of two photovoltaic cells 1a, 1b can be extended to the series connection of any number of photovoltaic cells 1. In order to connect at least three photovoltaic cells, the following stages are required: predisposing a plurality of photovoltaic cells 1 of the above-described type; ordering the predisposed photovoltaic cells 1 in a sequence; apart from the first photovoltaic cell 1, performing a series connection of the cell 1 and a preceding cell 1 in the sequence using the previously-described process.

Considering the counterpositioning between the trace junction 3a and the contract portion 10 of a single cell, using the above process series-connected rows of photovoltaic cells 1 can be made up, which rows can be series-connected to other parallel rows with a normal connection by means of transversal fingers 21, as in the prior art. The positioning of the transversal fingers 21 will be facilitated by the orientation, also transversal with respect to the row of cells of the trace junction 3a.

With the process of the present invention, the production of photovoltaic modules is easily automated: operations such as the depositing of photovoltaic cells 1 on a module and the superposing of the cells after application of a fixing substance with the aim of establishing an electrical connection between contacts of the contiguous cells can be performed without difficulty by Cartesian or anthropomorphic robots.

A photovoltaic cell 1, serially assembled according to the above-described process, comprises, like prior-art cells, a photosensitive semiconductor layer 2 provided with front contacts 3a, 3b and back contacts 4 arranged on opposite surfaces, the front contacts 3a, 3b comprising a trace junction 3a connected to secondary traces 3b. With respect to known devices, the cell is characterised in that the trace junction 3a is arranged in proximity of a first perimeter edge 6 of the cell.

The photosensitive semiconductor layer 2 is preferably made of crystalline silicon. As already mentioned in the description of the prior art, the uniform back contact 4 on the back of the cell is preferably made of aluminium and silver, while the front contacts 3a, 3b are made only of silver. These contacts are obtained by direct depositing on the photosensitive layer 2 of silver- and aluminium-based pastes using a silk-screening process.

In the illustrated embodiment of the accompanying figures of the drawings, the trace junction 3a develops linearly along the first perimeter edge 6 of the cell, which exhibits a square geometry. Cells can also have different geometries, for example rectangular or octagonal, without altering the condition of contiguity of the trace junction 3a to the perimeter edge. In the illustrated embodiment, the secondary traces or fingers 3b are straight traces and are perpendicular to the trace junction 3a, and extend from the first perimeter edge 6 of the cell to a second perimeter edge 7, opposite the first. The series connection of the photovoltaic cells described according to the present process enables an economically advantageous production of photovoltaic modules.

A photovoltaic module realised according to the process will comprise at least two photovoltaic cells 1a, 1b of the type comprising a photosensitive semiconductor layer 2 provided with front contacts 3a, 3b and back contacts 4, arranged on opposite surfaces, reciprocally connected in series by at least partial superposition of the front contact 3a, 3b of the second photovoltaic cell 1b on the back contact 4 of the first photovoltaic cell 1a.

1. A process for series connection of two photovoltaic cells (1a, 1b) in series, comprising following stages: predisposing a first photovoltaic cell (1a) and a second photovoltaic cell (1b), both of a type comprising a photosensitive semiconductor layer (2) provided with front contacts (3a, 3b) and back contacts (4) arranged on opposite surfaces of the cell; establishing an electrical connection between the front contact (3a, 3b) of the second photovoltaic cell (1b) and the back contact (4) of the first photovoltaic cell (1a); wherein the stage of establishing an electrical connection between the electrical contacts (3a, 3b, 4) of the photovoltaic cells comprises a stage of partially superposing the two photovoltaic cells (1a, 1b), causing at least a partial superposing of the back contact (4) of the first photovoltaic cell (1a) on the front contact (3a, 3b) of the second photovoltaic cell (1b) and consequently an electrical contact between the back contact (4) and the front contact (3a, 3b), a stage of electrically insulating the front contact (3a, 3b) from the back contact (4) of the first photovoltaic cell (1a) at the second perimeter edge (7) thereof, and a stage of electrically insulating the trace junction (3a) from the back contact (4) of the second photovoltaic cell (1b) at the first perimeter edge (6) by use of insulating lacquers or by burning the first perimeter edge (6).

2. The process for series connection of two photovoltaic cells (1a, 1b) of claim 1, wherein the front contact (3a, 3b) of the photovoltaic cells (1a, 1b) comprises at least a trace junction (3a) arranged in proximity of a first perimeter edge (6) of the cells, a contact portion (10) of the first photovoltaic cell (1a) being superposed on the trace junction (3a) during the stage of partially superposing the cells.

3. The process for series connection of two photovoltaic cells (1a, 1b) of claim 2, wherein the portion of contact (10) of the first photovoltaic cell (1a) is a lateral portion which is contiguous to a second perimeter edge (7) of the cell, the second edge being counterposed to the first perimeter edge (6).

4. The process for series connection of two photovoltaic cells (1a, 1b) of claim 3, wherein it comprises a stage of fixing the lower surface of the contact portion (10) of the first photovoltaic cell (1a) to the trace junction (3a) of the second photovoltaic cell (1b) by interposing a fixing substance (8) between the lower surface of the contact portion (10) and the trace junction (3a).

5. The process for series connection of two photovoltaic cells (1a, 1b) of claim 4, wherein the fixing substance (8) is constituted by an electrically-conductive paste which can solidify by sintering at a predetermined temperature.

6-7. (canceled)

8. A process for series connection of at least three photovoltaic cells (1) in series, comprising following stages: predisposing a plurality of photovoltaic cells (1) of a type comprising a photosensitive semiconductor layer (2) provided with front contacts (3a, 3b) and back contacts (4) arranged on opposite surfaces of the cell; ordering the photovoltaic cells (1) in a sequence; for each ordered photovoltaic cell (1) except the first thereof, creating a series connection between the photovoltaic cell (1) and a preceding photovoltaic cell (1) in the sequence; wherein at least one of the series connections between a photovoltaic cell (1) and a preceding photovoltaic cell (1) in sequence is realised using the process of claim 1.

9. The process for series connection of at least three photovoltaic cells (1) in series of claim 8, comprising a stage of depositing the photovoltaic cells (1) on a photovoltaic module, the stage of depositing the cells on the module, the stage of establishing an electrical connection between contacts and the stage of partially superposing the photovoltaic cells being done in an automated process by a robot.

10. A photovoltaic cell (1) assemblable in series with the process of claim 1, comprising a photosensitive semiconductor layer (2) provided with front contacts (3a, 3b) and back contacts (4) arranged on opposite surfaces, the front contacts (3a, 3b) comprising a trace junction (3a) connected to secondary traces (3b); wherein the trace junction (3a) is arranged in proximity of a first perimeter edge (6) of the cell.

11. The photovoltaic cell of claim 10, wherein the trace junction (3a) is developed linearly along the first perimeter edge (6) of the cell.

12. The photovoltaic cell of claim 11, wherein the secondary traces (3b) are straight and are perpendicular to the trace junction (3a), and extend from the first perimeter edge (6) to a second perimeter edge (7) of the cell, which second perimeter edge (7) is opposite the first perimeter edge (6).

13. A photovoltaic module made according to the process for series connection of photovoltaic cells as in claim 1, wherein it comprises at least two photovoltaic cells (1a, 1b) of a type comprising a photosensitive semiconductor layer (2) provided with front contacts (3a, 3b) and back contacts (4) arranged on opposite surfaces connected in series by at least partial superposing of the front contact (3a, 3b) of the first photovoltaic cell (1a) on the back contact (4) of the second photovoltaic cell (1b).
